(19) United States
(12) Patent Application Publication
(10) Pub. No.: US 2011/0156197 A1
(43) Pub. Date: Jun. 30, 2011

(54) Interwafer interconnects for stacked CMOS image sensors

(76) Inventors: Cristian A. Tivarus, Rochester, NY (US); John P. McCarten, Penfield, NY (US); Joseph R. Summa, Hilton, NY (US)

(21) Appl. No.: 12/655,549

(22) Filed: Dec. 31, 2009

(51) Int. Cl. H01L 27/146

(52) U.S. Cl. 257/444; 257/E27.133

(57) ABSTRACT

An image sensor includes a sensor wafer and a circuit wafer electrically connected to the sensor wafer. The sensor wafer includes unit cells with each unit cell having at least one photodetector and a charge-to-voltage conversion region. The circuit wafer includes unit cells with each unit cell having an electrical node associated with each unit cell on the sensor wafer. An inter-wafer interconnect is connected between each unit cell on the sensor wafer and a respective unit cell on the circuit wafer. The location of at least a portion of the inter-wafer interconnects is shifted or disposed at a different location with respect to the location of one or both components connected to the shifted inter-wafer interconnects. The locations of the inter-wafer interconnects can be disposed at different locations with respect to the locations of the charge-to-voltage conversion regions or with respect to the locations of the electrical nodes.

### TECHNICAL FIELD

The present invention relates generally to Complementary Metal Oxide Semiconductor (CMOS) image sensors, and more particularly to CMOS image sensors having two separate stacked semiconductor wafers with each wafer including a portion of the electrical circuitry. Still more particular, the present invention relates to inter-wafer interconnects for CMOS image sensors having two separate stacked semiconductor wafers.

### BACKGROUND

FIG. 1 is a cross-sectional view of an image sensor having two semiconductor wafers in an embodiment in accordance with the prior art. Sensor wafer 100 includes photodetectors 102, 104, charge-to-voltage conversion region 106(sw), and transfer gates 108, 110 for transferring photo-generated charge from photodetector 102, 104, respectively, to charge-to-voltage conversion region 106(sw).

Circuit wafer 112 includes support circuitry for the circuitry on sensor wafer 100. Inter-wafer interconnects 114 connect charge-to-voltage conversion regions 106(sw) to charge-to-voltage conversion regions 106(cw) on the circuit wafer 112. As shown in FIG. 1, the charge-to-voltage conversion regions 106(sw) and 106(cw) are vertically aligned with each other so that inter-wafer interconnect 114 follows a straight line between the two charge-to-voltage conversion regions.

FIG. 2 is a graphical illustration of a top view of a portion of sensor wafer 100. Sensor wafer 100 includes unit cells 200, with each unit cell having four photodetectors 102, 104, 202, 204, transfer gates 108, 110, 208, 210, charge-to-voltage conversion regions 106(sw), and inter-wafer interconnects 114 (shown in dashed lines). Interconnect pitch, or the distance between two adjacent inter-wafer interconnects or interconnect contacts, is one factor that influences the size and construction of stacked image sensors. In FIG. 2, the interconnect pitch between two column adjacent (in same row) inter-wafer interconnects is identified as distance a, while the interconnect pitch between two row adjacent (in same column) inter-wafer interconnects is identified as distance b. When distance b is greater than distance a, as can occur with rectangular shaped photodetectors, the minimum interconnect pitch is distance a.

Image sensors can have five to ten million pixels, with each pixel as small as 1.4 microns. And due to increasing demand for higher image resolutions, future image sensors will have even smaller sized pixels. With such small pixel sizes, the interconnect pitch can be a few microns. Unfortunately, current semiconductor fabrication processes are not always able to reliably fabricate the inter-wafer interconnects with such small interconnect pitches.

### SUMMARY

An image sensor includes a sensor wafer and a circuit wafer electrically connected to the sensor wafer. The sensor wafer has multiple unit cells with each unit cell including at least one photodetector and a charge-to-voltage conversion region. The circuit wafer includes unit cells with each unit cell having an electrical node that is associated with each unit cell on the sensor wafer. An inter-wafer interconnect is connected between each unit cell on the sensor wafer and a respective unit cell on the circuit wafer. At least a portion of the inter-wafer interconnects are shifted or disposed at different locations with respect to corresponding unit cells on the sensor and circuit wafers. The location of at least a portion of the inter-wafer interconnects is shifted or disposed at a different location with respect to the location of one or both components connected to the shifted inter-wafer interconnects. The inter-wafer interconnects can be shifted or disposed at different locations with respect to the locations of the charge-to-voltage conversion regions within at least a portion of the unit cells on the sensor wafer, with respect to the locations of the electrical nodes within at least a portion of the unit cells on the circuit wafer, or with respect to the locations of both the charge-to-voltage conversion regions within at least a portion of the unit cells on the sensor wafer and the electrical nodes within at least a portion of the unit cells on the circuit wafer. A conductive layer electrically connects each shifted inter-wafer interconnect to the charge-to-voltage conversion region or the electrical node connected to the shifted inter-wafer interconnect. At least a portion of the unit cells on one or both wafers may be shifted a predetermined distance with respect to the remaining unit cells on the sensor and circuit wafers.

### BRIEF DESCRIPTION OF THE DRAWINGS

Embodiments of the invention are better understood with reference to the following drawings. The elements of the drawings are not necessarily to scale relative to each other.

FIG. 1 is a cross-sectional view of an image sensor having two semiconductor wafers in accordance with the prior art;

FIG. 2 is a graphical illustration of a top view of a portion of sensor wafer 100 shown in FIG. 1;

FIG. 3 is a simplified block diagram of an image capture device in an embodiment in accordance with the invention;

FIG. 4 is a block diagram of a top view of an image sensor in an embodiment in accordance with the invention;

FIG. 5 is a schematic diagram of a first pixel architecture that can be implemented in an image sensor having two semiconductor wafers in accordance with the invention;

FIG. 6 is a schematic diagram of a first pixel architecture that can be implemented in an image sensor having two semiconductor wafers in accordance with the invention

FIG. 7 is a schematic diagram of a shared architecture that can be implemented in an image sensor having two semiconductor wafers in accordance with the invention;

FIG. 8 is a graphical illustration of a top view of a unit cell for the embodiment shown in FIG. 6;

FIG. 9 is a graphical illustration of a top view of an alternate unit cell in an embodiment in accordance with the invention;

FIG. 10 is a simplified expanded illustration of a portion of a first image sensor having two semiconductor wafers in an embodiment in accordance with the invention;

FIG. 11 is a graphical illustration of a top view of a portion of a first sensor wafer in an embodiment in accordance with the invention;

FIG. 12 is a graphical illustration of a top view of a portion of a second sensor wafer in an embodiment in accordance with the invention;

FIG. 13 is a cross-sectional view along line B-B in FIG. 12 in an embodiment in accordance with the invention;

FIG. 14 is a cross-sectional view along line C-C in FIG. 11 in an embodiment in accordance with the invention;

FIG. 15 is a simplified expanded illustration of a portion of a second image sensor having two semiconductor wafers in an embodiment in accordance with the invention;

FIG. 17 is a graphical illustration of a top view of a portion of a first sensor wafer with shifted interconnects in an embodiment in accordance with the invention;

FIG. 18 is a top view of a second sensor wafer with shifted interconnects in an embodiment in accordance with the invention;

FIG. 19 is a cross-sectional view of an image sensor along line D-D in FIG. 18 in an embodiment in accordance with the invention; and

FIG. 20 is a cross-sectional view of an alternate image sensor along line D-D in FIG. 18 in an embodiment in accordance with the invention.

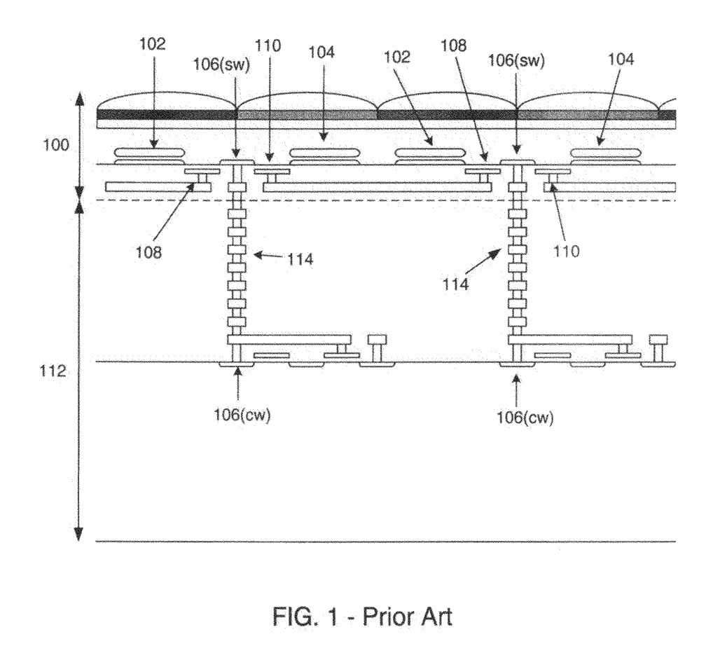

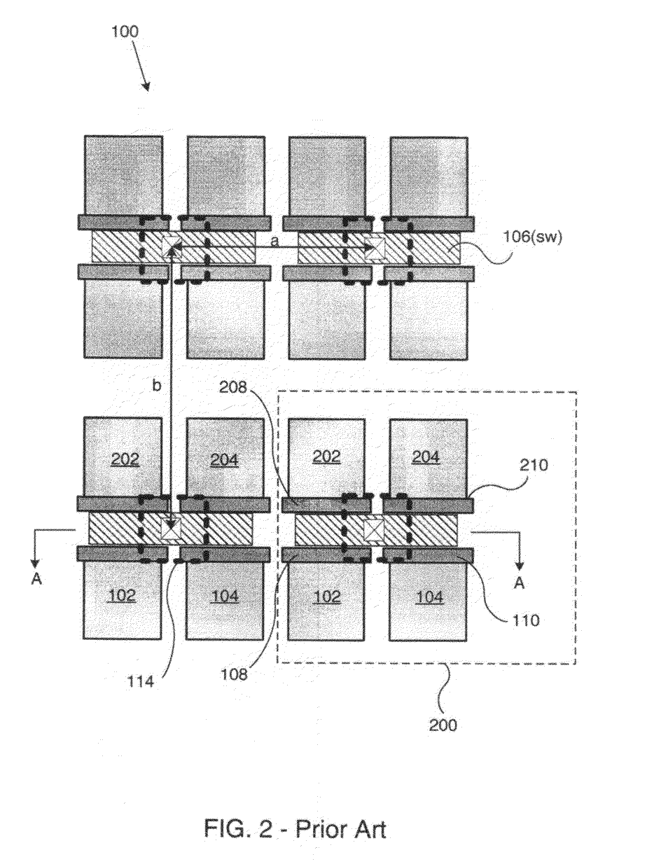

### DETAILED DESCRIPTION

Throughout the specification and claims, the following terms take the meanings explicitly associated herein, unless the context clearly dictates otherwise. The meaning of “a,” “an,” and “the” includes plural reference, the meaning of “in” includes “in” and “on.” The term “connected” means either a direct electrical connection between the items connected, or an indirect connection through one or more passive or active intermediary devices. The term “circuit” means either a single component or a multiplicity of components, either active or passive, that are connected together to provide a desired function. The term “signal” means at least one current, voltage, or data signal.

Additionally, directional terms such as “on”, “over”, “top”, “bottom”, are used with reference to the orientation of the Figure(s) being described. Because components of embodiments of the present invention can be positioned in a number of different orientations, the directional terminology is used for purposes of illustration only and is in no way limiting. When used in conjunction with layers of an image sensor wafer or corresponding image sensor, the directional terminology is intended to be construed broadly, and therefore should not be interpreted to preclude the presence of one or more intervening layers or other intervening image sensor features or elements. Thus, a given layer that is described herein as being formed on or formed over another layer may be separated from the latter layer by one or more additional layers.

And finally, the terms “wafer” and “substrate” are to be understood as a semiconductor-based material including, but not limited to, silicon, silicon-on-insulator (SOI) technology, silicon-on-sapphire (SOS) technology, doped and undoped semiconductors, epitaxial layers or well regions formed on a semiconductor substrate, and other semiconductor structures.

Referring to the drawings, like numbers indicate like parts throughout the views.

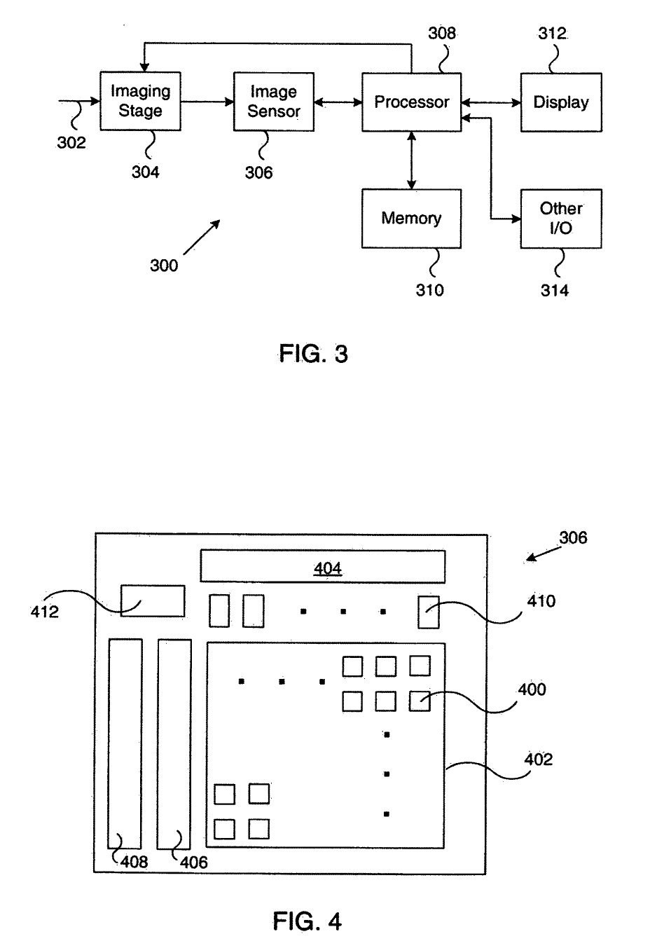

FIG. 3 is a simplified block diagram of an image capture device in an embodiment in accordance with the invention. Image capture device 300 is implemented as a digital camera in FIG. 3. Those skilled in the art will recognize that a digital camera is only one example of an image capture device that can utilize an image sensor incorporating the present invention. Other types of image capture devices, such as, for example, cell phone cameras, scanners, and digital video camcorders, can be used with the present invention.

In digital camera 300, light 302 from a subject scene is input to an imaging stage 304. Imaging stage 304 can include conventional elements such as a lens, a neutral density filter, an iris and a shutter. Light 302 is focused by imaging stage 304 to form an image on image sensor 306. Image sensor 306 captures one or more images by converting the incident light into electrical signals. Digital camera 300 further includes processor 308, memory 310, display 312, and one or more additional input/output (I/O) elements 314. Although shown as separate elements in the embodiment of FIG. 3, imaging stage 304 may be integrated with image sensor 306, and possibly one or more additional elements of digital camera 300, to form a camera module. For example, a processor or a memory may be integrated with image sensor 306 in a camera module in embodiments in accordance with the invention.

Processor 308 may be implemented, for example, as a microprocessor, a central processing unit (CPU), an application-specific integrated circuit (ASIC), a digital signal processor (DSP), or other processing device, or combinations of multiple such devices. Various elements of imaging stage 304 and image sensor 306 may be controlled by timing signals or other signals supplied from processor 308.

Memory 310 may be configured as any type of memory, such as, for example, random access memory (RAM), read-only memory (ROM), Flash memory, disk-based memory, removable memory, or other types of storage elements, in any combination. A given image captured by image sensor 306 may be stored by processor 308 in memory 310 and presented on display 312. Display 312 is typically an active matrix color liquid crystal display (LCD), although other types of displays may be used. The additional I/O elements 314 may include, for example, various on-screen controls, buttons or other user interfaces, network interfaces, or memory card interfaces.

It is to be appreciated that the digital camera shown in FIG. 3 may comprise additional or alternative elements of a type known to those skilled in the art. Elements not specifically shown or described herein may be selected from those known in the art. As noted previously, the present invention may be implemented in a wide variety of image capture devices. Also, certain aspects of the embodiments described herein may be implemented at least in part in the form of software executed by one or more processing elements of an image capture device. Such software can be implemented in a straightforward manner given the teachings provided herein, as will be appreciated by those skilled in the art.

Referring now to FIG. 4, there is shown a block diagram of a top view of an image sensor in an embodiment in accordance with the invention. Image sensor 306 includes a number of pixels 400 typically arranged in rows and columns that form a pixel array 402. Image sensor 306 further includes column decoder 404, row decoder 406, digital logic 408, multiple analog or digital output circuits 410, and timing generator 412. Each column of pixels 400 in pixel array 402 is electrically connected to an output circuit 410. Timing generator 412 generates the signals needed to read out signals from pixel array 402.

Image sensor 306 is implemented as an x-y addressable image sensor formed on two or more semiconductor wafers, such as, for example, a stacked Complementary Metal Oxide Semiconductor (CMOS) image sensor, in an embodiment in accordance with the invention. Thus, column decoder 404, row decoder 406, digital logic 408, analog or digital output channels 410, and timing generator 412 are implemented as standard CMOS electronic circuits that are operatively connected to pixel array 400.

Functionality associated with the sampling and readout of pixel array 402 and the processing of corresponding image data may be implemented at least in part in the form of software that is stored in memory 410 (see FIG. 4) and executed by processor 408. Portions of the sampling and readout circuitry may be arranged external to image sensor 306, or formed integrally with pixel array 402, for example, on a common integrated circuit with photodetectors and other elements of the pixel array. Those skilled in the art will recognize that other peripheral circuitry configurations or architectures can be implemented in other embodiments in accordance with the invention.

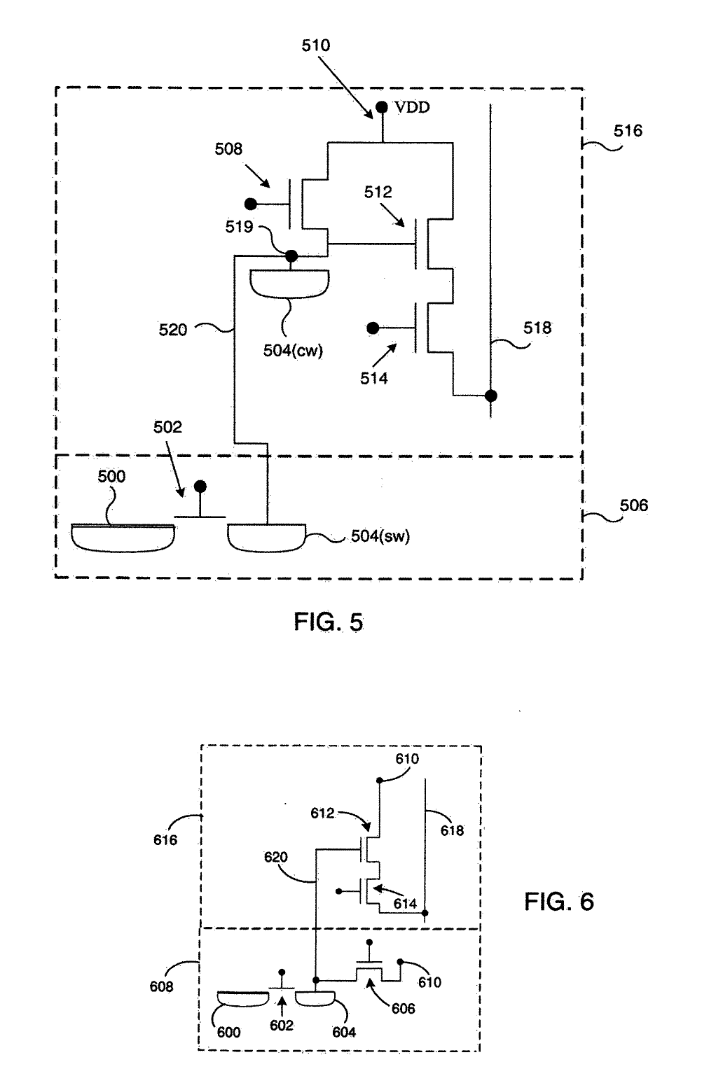

FIG. 5 is a schematic diagram of a first pixel architecture that can be implemented in an image sensor having two semiconductor wafers in accordance with the invention. Photodetector 500, transfer gate 502, and charge-to-voltage conversion region 504(sw) are disposed on sensor wafer 506. Photodetector 500, transfer gate 502, and charge-to-voltage conversion region 504 (sw) form an exemplary unit cell on sensor wafer 506 in an embodiment in accordance with the invention.

Charge-to-voltage conversion region 504(cw), reset transistor 508, potential V_{DD} 510, amplifier 2, and row select transistor 514 are constructed on circuit wafer 516. Charge-to-voltage conversion regions 504(sw), 504(cw) are implemented as floating diffusions and amplifier 512 as a source follower transistor in an embodiment in accordance with the invention. One source/drain electrode of row select transistor 514 is connected to a source/drain electrode of amplifier 512, while the other source/drain electrode of row select transistor 514 is connected to output line 518. A source/drain electrode of both reset transistor 508 and amplifier 512 is maintained at potential V_{DD} 510. Electrical node 519 connects together the other source/drain electrode of reset transistor 508, the gate of amplifier 512, and charge-to-voltage conversion region 504(cw).

Inter-wafer interconnect 520 connects charge-to-voltage conversion region 504(sw) on sensor wafer 506 to electrical node 519 on circuit wafer 516.

Photodetector 500 collects charge in response to incident light. Transfer gate 502 selectively passes the collected charge from photodetector 500 to charge-to-voltage conversion region 504(sw). Inter-wafer interconnect 520 transmits the charge from charge-to-voltage conversion region 504(sw) on sensor wafer 506 to charge-to-voltage conversion region 504(cw) on circuit wafer 516.

Charge-to-voltage conversion region 504(cw) converts the charge to a voltage which is then sensed and buffered by amplifier 512. The voltage is transferred to output line 518 when row select transistor 514 is enabled. Reset transistor 508 is used to reset charge-to-voltage conversion regions 504(sw), 504(cw) to the known potential 510.

Charge-to-voltage conversion region 504(cw) and amplifier 512 are included in a unit cell on circuit wafer 516 in an embodiment in accordance with the invention. Reset transistor 508 and row select transistor 514, either individually or in combination, may be included in the unit cell on circuit wafer 516 in other embodiments in accordance with the invention.

FIG. 6 is a schematic diagram of a second pixel architecture that can be implemented in an image sensor having two semiconductor wafers in an embodiment in accordance with the invention. Photodetector 600, transfer gate 602, charge-to-voltage conversion region 604, and reset transistor 606 are disposed on sensor wafer 608. One source/drain electrode of reset transistor 606 is connected to charge-to-voltage conversion region 604 while the other source/drain electrode of reset transistor 606 is maintained at potential V_{DD} 610. Photodetector 600, transfer gate 602, charge-to-voltage conversion region 604, and reset transistor 606 form an exemplary unit cell on sensor wafer 608 in an embodiment in accordance with the invention.

Amplifier 612 and row select transistor 614 are constructed on circuit wafer 616. One source/drain electrode of row select transistor 614 is connected to a source/drain electrode of amplifier 612 while the other source/drain electrode of row select transistor 614 is connected to output line 618. The other source/drain electrode of amplifier 612 is maintained at potential V_{DD} 610. Charge-to-voltage conversion region 604 is implemented as a floating diffusion and amplifier 612 as a source follower transistor in an embodiment in accordance with the invention.

Inter-wafer interconnect 620 connects charge-to-voltage conversion region 604 on sensor wafer 608 to the gate of amplifier 612 on circuit wafer 616. The gate of amplifier 612 is considered an electrical node on circuit wafer 616 in an embodiment in accordance with the invention. Additionally, amplifier 612 is included in a unit cell on circuit wafer 616 in an embodiment in accordance with the invention. Row select transistor 614 may be included in the unit cell on circuit wafer 616 in other embodiments in accordance with the invention.

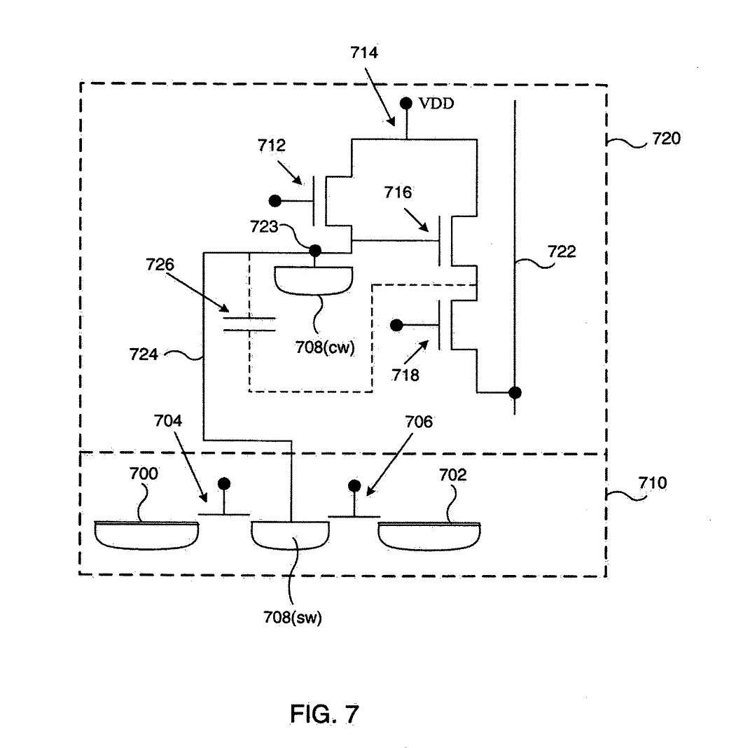

Referring now to FIG. 7, there is shown a schematic diagram of a shared architecture that can be implemented in an image sensor having two semiconductor wafers in an embodiment in accordance with the invention. Two photodetectors 700, 702, two transfer gates 704, 706, and a charge-to-voltage conversion region 708(sw) are disposed on sensor wafer 710. The two photodetectors 700, 702, two transfer gates 704, 706, and charge-to-voltage conversion region 708(sw) form an exemplary unit cell on sensor wafer 710 in an embodiment in accordance with the invention.

Charge-to-voltage conversion region 708(cw), reset transistor 712, potential V_{DD} 714, amplifier 716, and row select transistor 718 are constructed on circuit wafer 720. Charge-to-voltage conversion regions 708(sw), 708(cw) are implemented as floating diffusions and amplifier 716 as a source follower transistor in an embodiment in accordance with the invention. One source/drain electrode of row select transistor 718 is connected to a source/drain electrode of amplifier 716 while the other source/drain electrode is connected to output line 722. One source/drain electrode of both reset transistor 712 and amplifier 716 is maintained at potential V_{DD} 714. Electrical node 723 connects together the other source/drain electrode of reset transistor 712, the gate of amplifier 716, and charge-to-voltage conversion region 708(cw).

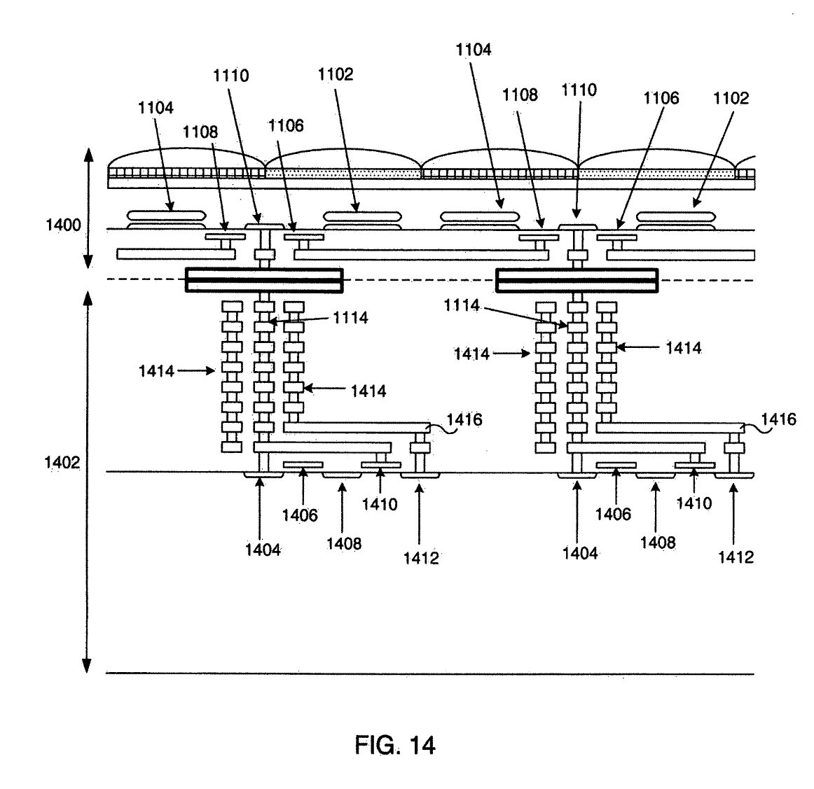

Inter-wafer interconnect 724 electrically connects charge-to-voltage conversion region 708(sw) on sensor wafer 710 to electrical node 723 on circuit wafer 720. Capacitor 726 represents the capacitance between inter-wafer interconnect 724 and a shield (not shown in FIG. 7), which is described in more detail in conjunction with FIG. 14.

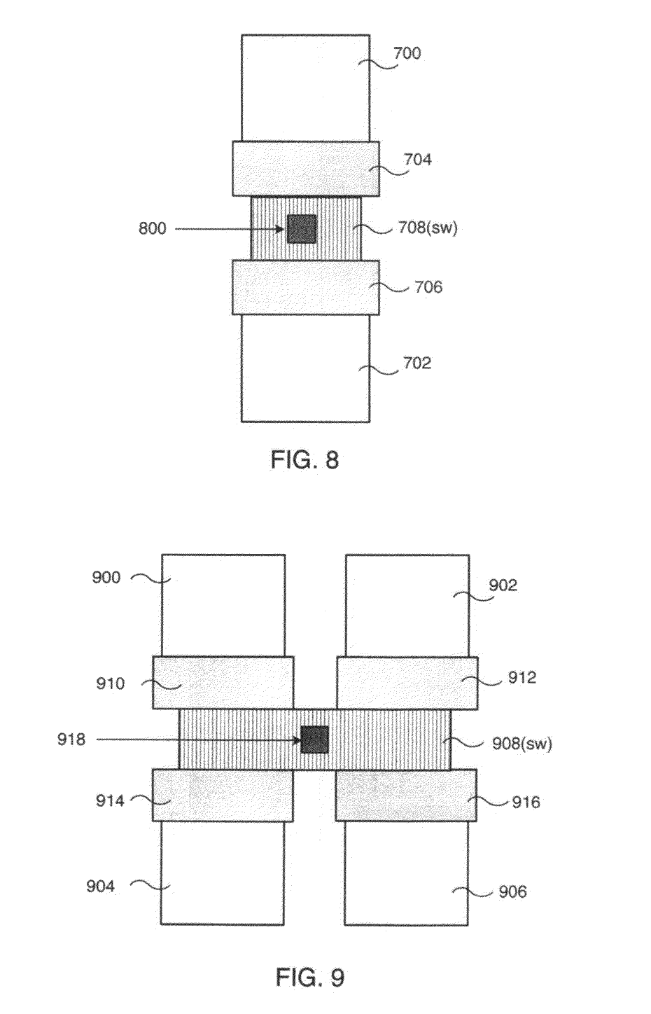

FIG. 8 is a graphical illustration of a top view of a unit cell for the embodiment shown in FIG. 7. As described earlier, each photodetector 700, 702 collects charge in response to incident light. Transfer gates 704, 706 selectively and respectively pass the collected charge from photodetectors 700, 702 to shared charge-to-voltage conversion region 708(sw). Contact 800 is electrically connected to inter-wafer interconnect 724.

FIG. 9 is a graphical illustration of a top view of an alternate unit cell in an embodiment in accordance with the invention. In the embodiment shown in FIG. 9, four photodetectors 900, 902, 904, 906 share one charge-to-voltage conversion region 908(sw) on a sensor wafer. Transfer gates 910, 912, 914, 916 selectively and respectively pass charge from photodetectors 900, 902, 904, 906 to shared charge-to-voltage conversion region 908(sw). Photodetectors 900, 902 are typically disposed in one row (or column) of pixels in a pixel array and photodetectors 904, 906 are in an adjacent row (or column) in the pixel array.

Contact 918 is electrically connected to an inter-wafer interconnect. The inter-wafer interconnect electrically connects charge-to-voltage conversion region 908(sw) to a respective electrical node on a circuit wafer. The electrical node can be connected to a charge-to-voltage conversion region or an amplifier in one or more embodiments in accordance with the invention. By way of example only, the circuit wafer is configured like circuit wafer 720 shown in FIG. 7 in an embodiment in accordance with the invention.

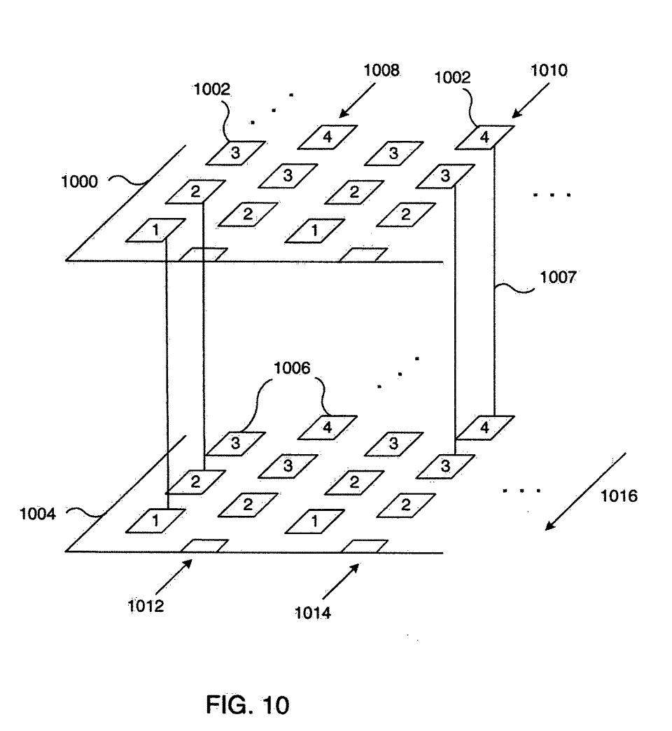

Referring now to FIG. 10, there is shown a simplified illustration of a portion of a first image sensor having two semiconductor wafers in an embodiment in accordance with the invention. Sensor wafer 1000 includes multiple unit cells 1002. Each unit cell 1002 includes at least one photodetector and a charge-to-voltage conversion region (not shown).

Circuit wafer 1004 also includes multiple unit cells 1006. In the FIG. 10 embodiment, each unit cell 1006 includes a charge-to-voltage conversion region (not shown). Unit cells 1002, 1006 are labeled 1, 2, 3, and 4 and are arranged in rows and columns. The ellipses indicate more unit cells 1002, 1006 are present on sensor and circuit wafers 1000, 1004.

An inter-wafer interconnect 1007 electrically connects each charge-to-voltage conversion region on the sensor wafer 1000 to an electrical node on the circuit wafer 1004. The electrical node connects to a charge-to-voltage conversion region in the embodiment shown in FIG. 10. In another embodiment in accordance with the invention, the electrical node is a gate of an amplifier as depicted in FIG. 6.

The unit cells labeled “1”, “2”, “3”, “4” on the sensor and circuit wafers represent corresponding unit cells that in a prior art image sensor would be in the same rows on both wafers. Embodiments in accordance with the invention shift the locations of a portion of the unit cells 1002 on sensor wafer 1000 and the locations of corresponding unit cells 1006 on circuit wafer 1004 with respect to the other unit cells on the wafers. In the embodiment of FIG. 10, the locations of unit cells in every other column 1008, 1010 of unit cells on the sensor wafer 1002 and corresponding columns 1012, 1014 on the circuit wafer 1004 are shifted in the direction indicated by arrow 1016. The locations of the unit cells in columns 1008, 1010, 1012, 1014 are shifted by one row of photodetectors in an embodiment in accordance with the invention. Other embodiments in accordance with the invention can shift the location of unit cells in any direction, any distance, or a combination of both direction and distance. The distance can include, but is not limited to, a fraction of a row, multiple rows, or some combination thereof.

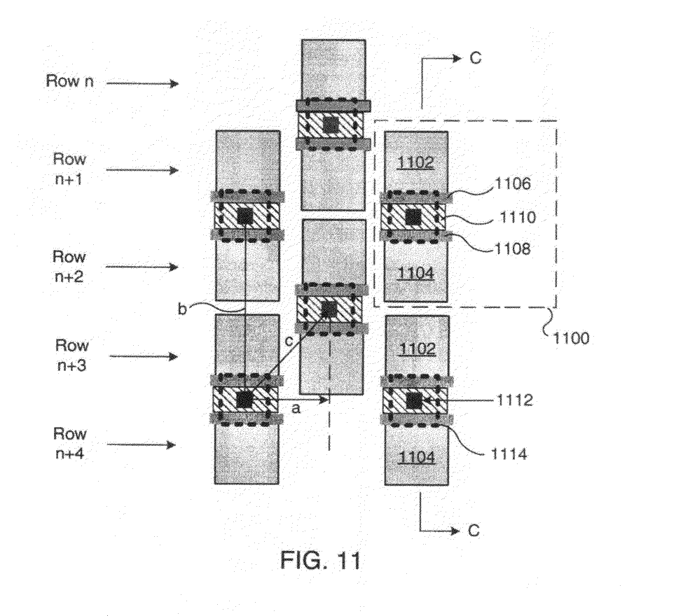

Shifting the location of a portion of corresponding unit cells 1002, 1006 on both the sensor wafer and the circuit wafer increases the interconnect pitch, which will now be described with reference to FIG. 11.

FIG. 11 is a graphical illustration of a top view of a portion of a first sensor wafer in an embodiment in accordance with the invention. When the locations of the unit cells in every other column of unit cells are shifted up or down by one row of photodetectors, the minimum interconnect pitch “c” can be expressed mathematically as

$$C = \sqrt{\frac{{a}^{2} + {b}^{2}}{4}} ,$$

where “b” is the distance between two row adjacent (in same column) inter-wafer interconnects and “a” is the distance perpendicular to “b” between two column adjacent (in same row) interconnects. When b=a, the interconnect pitch increases in one direction (horizontal direction) from a to 1.118a, a 12% increase. In the vertical direction, the interconnect pitch is a. Increasing the interconnect pitch in the horizontal direction can make the fabrication process for the image sensor more reliable.

Table 1 lists the minimum interconnect pitches in percentages for values of b ranging from 1.0a to 2.0a when every other column of unit cells is shifted up or down by one row of photodetectors.

TABLE 1

| b | sqrt(a\hat{ }2 + b\hat{ }2/4) | pitch |
|---|---|---|
| (units of a) | (units of a) | increase in % |
| 1 | 1.118033989 | 12 |
| 1.1 | 1.141271221 | 14 |
| 1.2 | 1.166190379 | 17 |
| 1.3 | 1.192686044 | 19 |
| 1.4 | 1.220655562 | 22 |
| 1.5 | 1.25 | 25 |
| 1.6 | 1.280624847 | 28 |
| 1.7 | 1.312440475 | 31 |
| 1.8 | 1.345362405 | 35 |
| 1.9 | 1.379311422 | 38 |
| 2 | 1.414213562 | 41 |

Each unit cell 1100 in FIG. 11 includes two photodetectors 1102, 1104, two transfer gates 1106, 1108, and one charge-to-voltage conversion region 1110 shared by the two photodetectors 1102, 1104. Contacts 1112 are electrically connected to inter-wafer interconnects 1114 (represented by dashed lines).

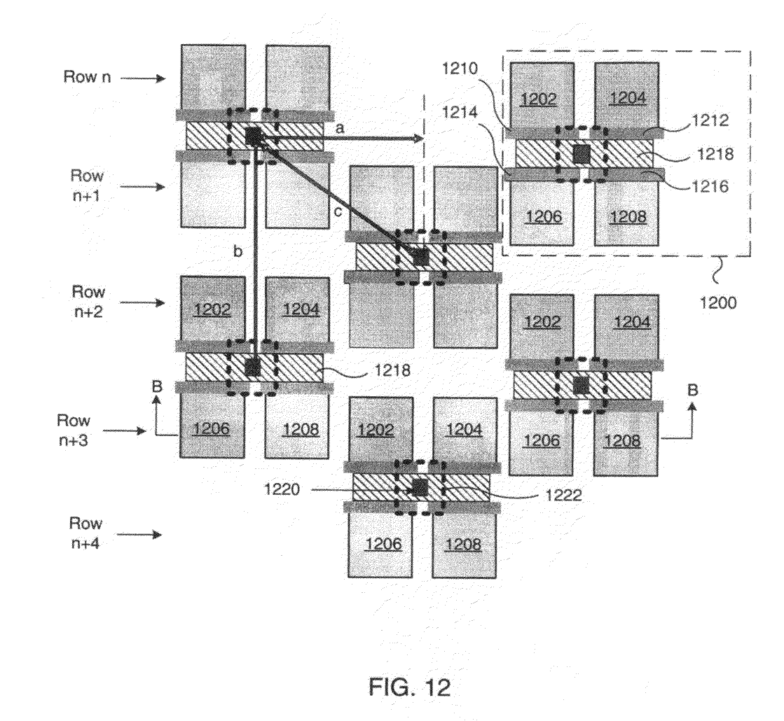

FIG. 12 is a graphical illustration of a top view of a portion of a second sensor wafer in an embodiment in accordance with the invention. Each unit cell 1200 in FIG. 12 includes four photodetectors 1202, 1204, 1206, 1208, four transfer gates 1210, 1212, 1214, 1216, and one charge-to-voltage conversion region 1218 shared by the four photodetectors 1202, 1204, 1206, 1208. Contacts 1220 are electrically connected to inter-wafer interconnects 1222 (represented by dashed lines). The values in Table 1 apply to the embodiment shown in FIG. 12 when the locations of unit cells in alternating columns of unit cells are shifted up one row of photodetectors.

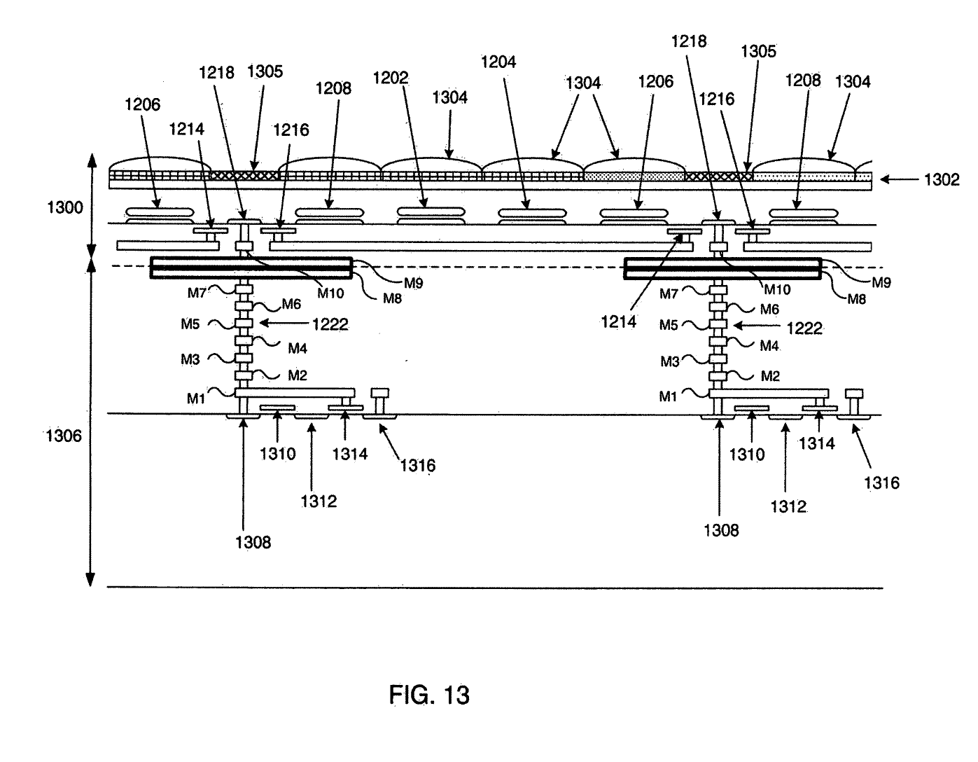

Referring now to FIG. 13, there is shown a cross-sectional view along line B-B in FIG. 12 in an embodiment in accordance with the invention. Sensor wafer 1300 includes photodetectors 1202, 1204, 1206, 1208, transfer gates 1214, 1216, and charge-to-voltage conversion regions 1218. A color filter array (CFA) 1302 and microlenses 1304 are disposed on a surface of sensor wafer 1300. A black color filter element 1305 (in CFA 1302) can be disposed over charge-to-voltage conversion regions 1218 in an embodiment in accordance with the invention.

Circuit wafer 1306 includes charge-to-voltage conversion regions 1308, gates 1310 of reset transistors, potential VDD 1312, a gate 1314 of an amplifier, and outputs 1316 of the amplifier. Inter-wafer interconnects 1222 electrically connect charge-to-voltage conversion regions 1218 on the sensor wafer 1300 to charge-to-voltage conversion regions 1308 on the circuit wafer 1306 in the embodiment shown in FIG. 13. Inter-wafer interconnects 1222 are constructed with conductive segments disposed between metal layers M1-M10. Metal layers M8 and M9 form a wafer-to-wafer electrical interconnect disposed at the interface between sensor wafer 1300 and circuit wafer 1306.

FIG. 14 is a cross-sectional view along line C-C in FIG. 11 in an embodiment in accordance with the invention. Sensor wafer 1400 includes photodetectors 1102, 1104, transfer gates 1106, 1108, and charge-to-voltage conversion regions 1110. Circuit wafer 1402 includes charge-to-voltage conversion regions 1404, gates 1406 of reset transistors, potential VDD 1408, gates 1410 of an amplifier, and outputs 1412 of the amplifier. Inter-wafer interconnects 1114 electrically connect charge-to-voltage conversion regions 1110 on the sensor wafer 1400 to charge-to-voltage conversion regions 1404 on the circuit wafer 1402 in the embodiment shown in FIG. 14.

Inter-wafer interconnects 1114 are surrounded by an optional metal shield 1414. Metal shield 1414 consists of metal segments in each metal layer. The metal shield 1414 is electrically connected to the output 1412 of the amplifier through electrical connector 1416. Connecting metal shield 1414 to output 1412 reduces the effective capacitance of charge-to-voltage conversion region 1404. Additionally, metal shield 1414 reduces the capacitive coupling between adjacent wires of inter-wafer interconnects 1114, which reduces electrical crosstalk.

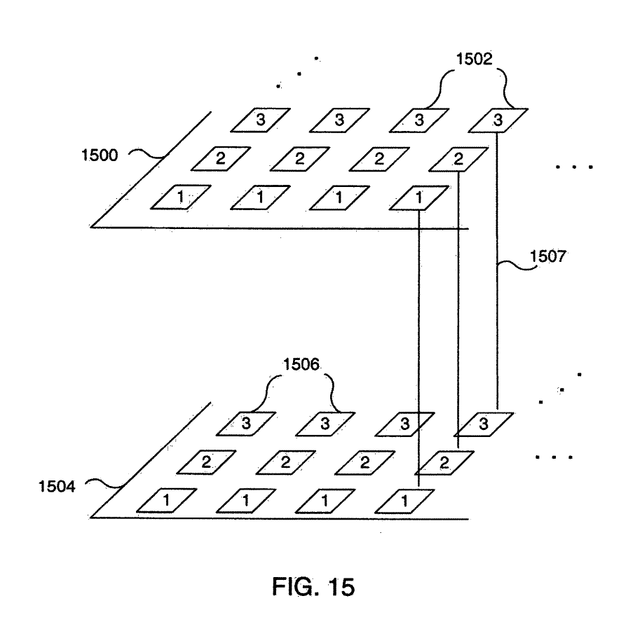

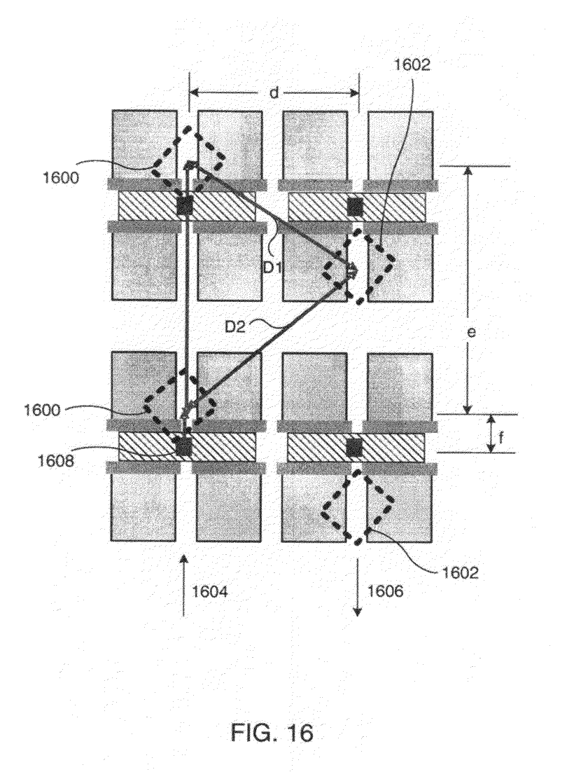

Referring now to FIG. 15, there is shown a simplified illustration of a portion of a second image sensor having two semiconductor wafers in an embodiment in accordance with the invention. Sensor wafer 1500 includes multiple unit cells 1502. Each unit cell 1502 includes at least one photodetector and a charge-to-voltage conversion region (not shown) in an embodiment in accordance with the invention.

Circuit wafer 1504 also includes multiple unit cells 1506. The ellipses indicate more unit cells 1502, 1506 are present on sensor and circuit wafers 1500, 1504, respectively. An inter-wafer interconnect 1507 electrically connects each charge-to-voltage conversion region on the sensor wafer to an electrical node on the circuit wafer. The electrical node can connect, for example, to a charge-to-voltage conversion region as shown in FIGS. 5 and 7, or to a gate of an amplifier as depicted in FIG. 6.

In one embodiment in accordance with the invention, the location of at least a portion of inter-wafer interconnects 1507 is shifted or disposed at a different location with respect to a component on either the sensor or circuit wafer connected to the shifted inter-wafer interconnects. In another embodiment in accordance with the invention, the location of at least a portion of inter-wafer interconnects 1507 are shifted or disposed at a different location with respect to the components on both wafers that are connected to the shifted inter-wafer interconnects. The unit cells on one or both wafers may or may not be shifted with respect to each other, or shifted with respect to other unit cells on the same wafer. Shifting the locations of at least a portion of the inter-wafer interconnects can increase the interconnect pitch, which will now be described with reference to FIG. 16.

FIG. 16 is a graphical illustration of a top view of a portion of a first sensor wafer with shifted interconnects in an embodiment in accordance with the invention. Inter-wafer interconnects 1600, 1602 are depicted with dashed lines at their respective shifted locations. Arrow 1604 represents the direction of shift for the locations of inter-wafer interconnects 1600 while arrow 1606 represents the direction of shift for the locations of inter-wafer interconnects 1602.

In FIG. 16, the distance “d” is the distance along an x-axis between two column adjacent (in the same row) inter-wafer interconnects 1600, 1602. The distance “e” is the distance along a y-axis between two row adjacent (in the same column) inter-wafer interconnects 1600. Distance “f” is the distance between one inter-wafer interconnect 1600 and contact 1608. The minimum interconnect pitch D1 between the two column adjacent inter-wafer interconnects 1600, 1602 is expressed mathematically as

D1=\sqrt{d²+4f²}

The minimum interconnect pitch D2 between two inter-wafer interconnects 1600 in the same column is expressed mathematically as

D2=\sqrt{d²+(e−2f)²}

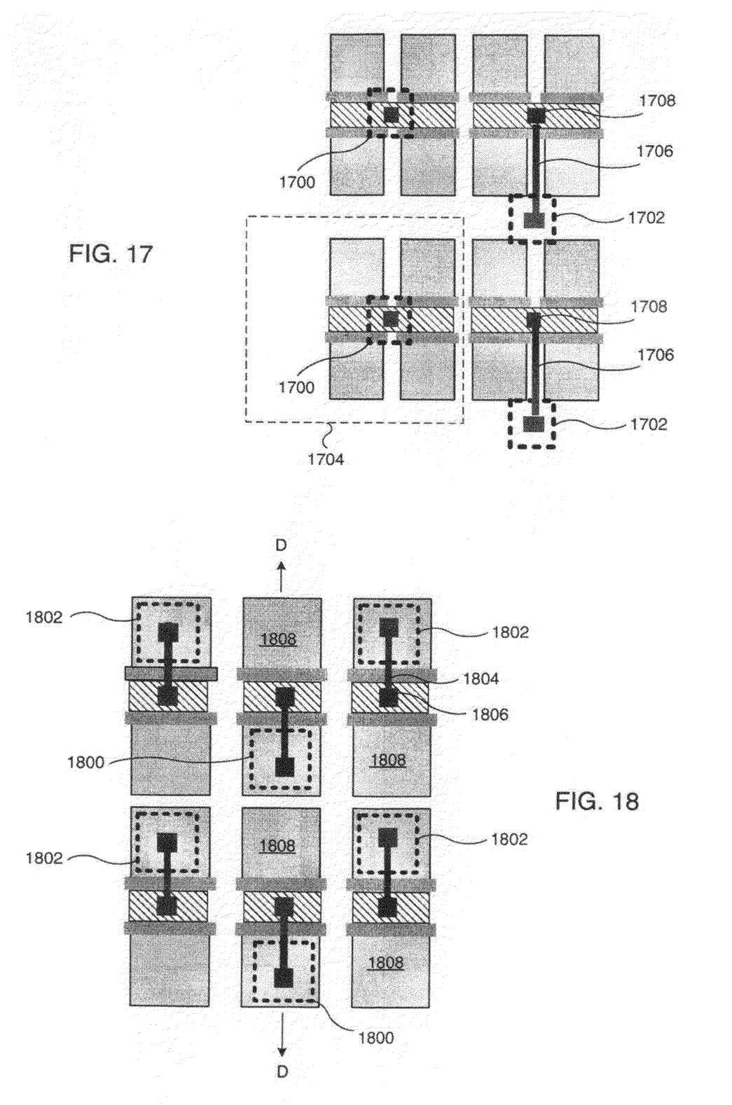

All of the inter-wafer interconnects 1600, 1602 are shifted to locations between two photodetectors in the embodiment shown in FIG. 16. Other embodiments in accordance with the invention can shift the locations of a portion of the inter-wafer interconnects with respect to a component on one wafer, or shift the locations of a portion of the inter-wafer interconnects with respect to components on both wafers. FIGS. 17-18 illustrate alternate top views of a sensor wafer with shifted interconnect locations in an embodiment in accordance with the invention.

In FIG. 17, the locations of inter-wafer interconnects 1700 are not shifted while the locations of the inter-wafer interconnects 1702 are shifted with respect to adjacent unit cells 1704 on the sensor wafer. A conductive layer 1706 electrically connects inter-wafer interconnects 1072 to respective contacts 1708. In FIG. 17, the locations of inter-wafer interconnects in every other column are shifted. Other embodiments can shift a portion of the locations of inter-wafer interconnects differently. By way of example only, the locations of inter-wafer interconnects in every other row can be shifted.

The embodiment shown in FIG. 18 shifts all of the locations of inter-wafer interconnects, with the locations of a portion 1800 shifted in one direction and the locations of another portion 1802 shifted in the opposite direction. A conductive layer 1804 electrically connects inter-wafer interconnects 1800, 1802 to respective contacts 1806. In FIG. 18, the locations of inter-wafer interconnects are shifted a distance equal to one-half the length of a photodetector 1808. Other embodiments can shift the locations of the inter-wafer interconnects differently.

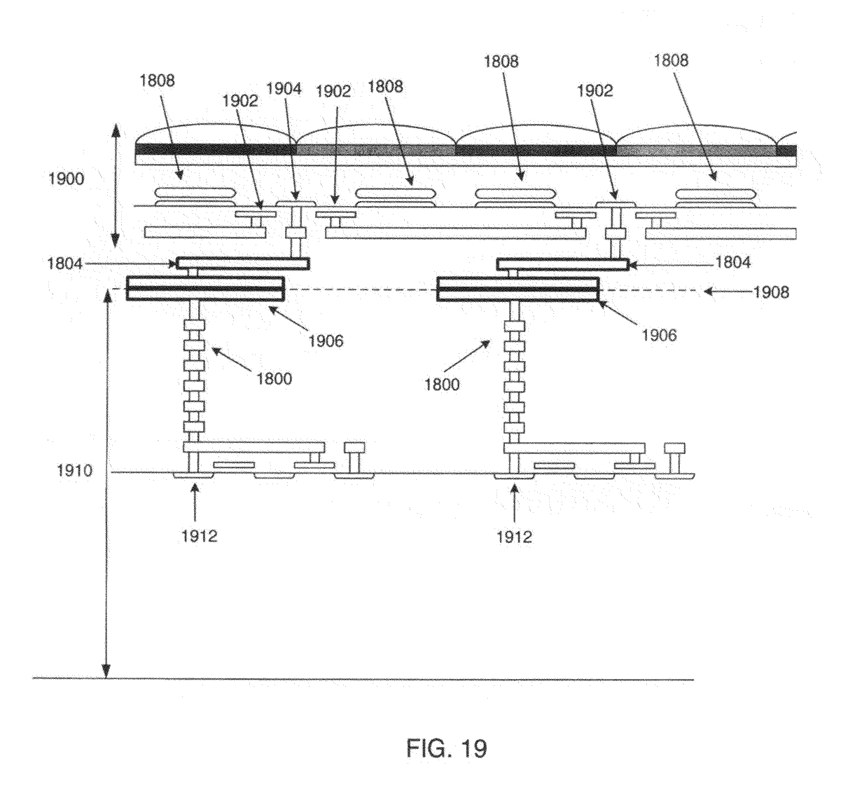

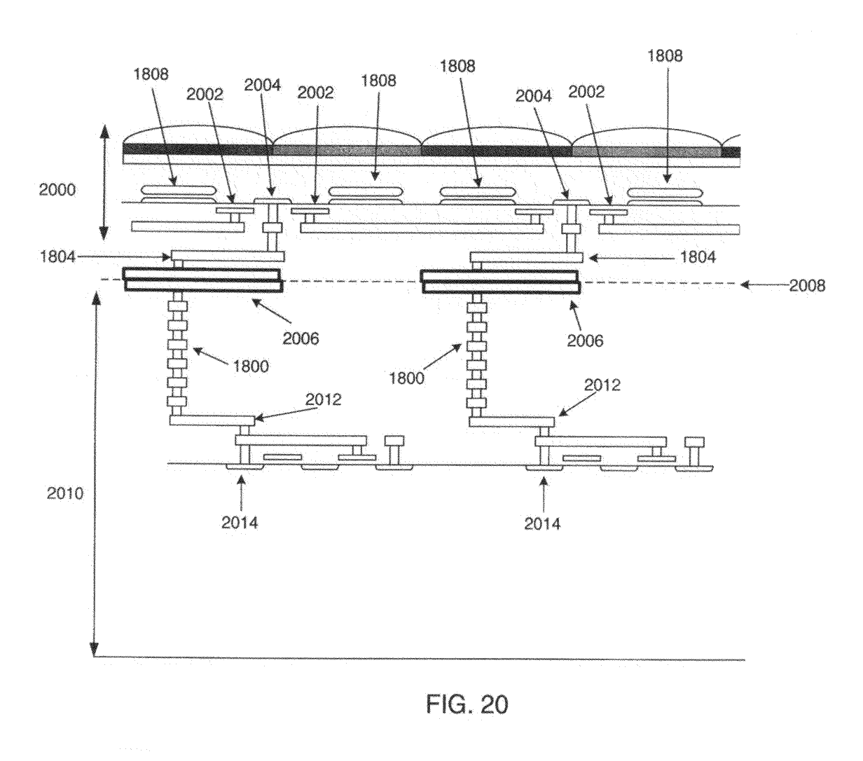

Referring now to FIG. 19, there is shown a cross-sectional view of an image sensor along line D-D in FIG. 18 in an embodiment in accordance with the invention. Sensor wafer 1900 includes photodetectors 1808, transfer gates 1902, and charge-to-voltage conversion regions 1904. Conductive layer 1804 electrically connects charge-to-voltage conversion regions 1904 to respective ends of inter-wafer interconnects 1800. Conductive layer 1804 is formed with an additional metal layer in an embodiment in accordance with the invention.

A wafer-to-wafer electrical interconnect 1906 is disposed at the interface 1908 between sensor wafer 1900 and circuit wafer 1910. Inter-wafer interconnects 1800 electrically connect charge-to-voltage conversion regions 1904 on the sensor wafer 1900 to charge-to-voltage conversion regions 1912 on circuit wafer 1910 in an embodiment in accordance with the invention. As shown in FIG. 19, the locations of inter-wafer interconnects 1800 are shifted or disposed at different locations with respect to corresponding unit cells on the sensor and circuit wafers. In the illustrated embodiment, the locations of inter-wafer interconnects 1800 are shifted or disposed at a different location with respect to one component that is connected to the inter-wafer interconnects 1800. The inter-wafer interconnects 1800 are shifted or disposed at different locations with respect to the locations of charge-to-voltage conversion regions 1904 on the sensor wafer 1900. Inter-wafer interconnects 1800 do not follow a straight line between charge-to-voltage conversion regions 1904 on sensor wafer 1900 and charge-to-voltage conversion regions 1912 on circuit wafer 1910.

FIG. 19 depicts conductive layer 1804 between charge-to-voltage conversion region 1904 on sensor wafer 1900 and inter-wafer interconnect 1800. In another embodiment in accordance with the invention, the inter-wafer interconnects 1800 are shifted or disposed at different locations with respect to the locations of charge-to-voltage conversion regions 1912 on the circuit wafer 1910. Conductive layer 1804 would therefore electrically connect charge-to-voltage conversion region 1912 to inter-wafer interconnect 1800.

Additionally, inter-wafer interconnects 1800 can connect charge-to-voltage conversion region 1904 on sensor wafer 1900 to a gate of an amplifier in yet another embodiment in accordance with the invention. Conductive layer 1804 can be used to connect charge-to-voltage conversion region 1904 on sensor wafer 1900 to inter-wafer interconnect 1800 or to connect the gate of the amplifier on circuit wafer 1910 to inter-wafer interconnect 1800.

FIG. 20 is a cross-sectional view of an alternate image sensor along line D-D in FIG. 18 in an embodiment in accordance with the invention. Sensor wafer 2000 includes photodetectors 1808, transfer gates 2002, and charge-to-voltage conversion regions 2004. Conductive layer 1804 electrically connects charge-to-voltage conversion regions 2004 to respective ends of inter-wafer interconnects 1800.

A wafer-to-wafer electrical interconnect 2006 is disposed at the interface 2008 between sensor wafer 2000 and circuit wafer 2010. Conductive layer 2012 electrically connects inter-wafer interconnects 1800 to respective charge-to-voltage conversion regions 2014 in an embodiment in accordance with the invention. Conductive layers 1804 and 2012 are each formed with an additional metal layer in an embodiment in accordance with the invention.

As shown in FIG. 20, the locations of inter-wafer interconnects 1800 are shifted or disposed at a different location with respect to both components connected to the shifted inter-wafer interconnects 1800. In the illustrated embodiment, the locations of inter-wafer interconnects 1800 are shifted or disposed at different locations with respect to the locations of charge-to-voltage conversion regions 2004 on sensor wafer 2000 and with respect to the locations of charge-to-voltage conversion regions 2014 on circuit wafer 2010. Inter-wafer interconnects 1800 do not follow a straight line between charge-to-voltage conversion regions 2004 on sensor wafer 2000 and charge-to-voltage conversion regions 2014 on circuit wafer 2010.

Alternatively, inter-wafer interconnects 1800 can connect charge-to-voltage conversion region 2004 on sensor wafer 2000 to a gate of an amplifier on circuit wafer 2010 in other embodiments in accordance with the invention. Conductive layers 1804, 2012 can be used to electrically connect inter-wafer interconnect 1800 to charge-to-voltage conversion region 2004 and to the gate of the amplifier on circuit wafer 2010, respectively.

The invention has been described in detail with particular reference to certain preferred embodiments thereof, but it will be understood that variations and modifications can be effected within the spirit and scope of the invention. For example, the photodetectors have been described as being positioned on a single sensor wafer. Other embodiments in accordance with the invention can include the photodetectors on two or more sensor wafers. An image sensor having multiple sensor layers is disclosed in commonly assigned U.S. patent application Ser. No. 12/184,314 filed on Aug. 1, 2008.

Even though specific embodiments of the invention have been described herein, it should be noted that the application is not limited to these embodiments. In particular, any features described with respect to one embodiment may also be used in other embodiments, where compatible. And the features of the different embodiments may be exchanged, where compatible.

### PARTS LIST

100 sensor wafer
102 photodetector
104 photodetector
106(sw) charge-to-voltage conversion region
106(cw) charge-to-voltage conversion region
108 transfer gate
110 transfer gate
112 circuit wafer
114 inter-wafer interconnect
200 unit cell
202 photodetector
204 photodetector
208 transfer gate
210 transfer gate
300 image capture device
302 light
304 imaging stage
306 image sensor
308 processor
310 memory
312 display
314 other input/output
400 pixel
402 pixel array
404 column decoder
406 row decoder
408 digital logic
410 analog or digital output circuits
412 timing generator
500 photodetector
502 transfer gate
504(sw) charge-to-voltage conversion region on sensor wafer
504(cw) charge-to-voltage conversion region on circuit wafer
506 sensor wafer
508 reset transistor
510 potential
512 amplifier
514 row select transistor
516 circuit wafer
518 output line
519 electrical node
520 inter-wafer interconnect
600 photodetector
602 transfer gate
604 charge-to-voltage conversion region
606 reset transistor
608 sensor wafer
610 potential
612 amplifier
614 row select transistor
616 circuit wafer
618 output line
620 inter-wafer interconnect
700 photodetector
702 photodetector
704 transfer gate
706 transfer gate
708(sw) charge-to-voltage conversion region on sensor wafer
708(cw) charge-to-voltage conversion region on circuit wafer
710 sensor wafer
712 reset transistor
714 potential
716 amplifier
718 row select transistor
720 circuit wafer
722 output line
723 electrical node
724 inter-wafer interconnect
726 capacitance
800 contact
900 photodetector
902 photodetector
904 photodetector
906 photodetector
908(sw) charge-to-voltage conversion region on sensor wafer
910 transfer gate
912 transfer gate
914 transfer gate
916 transfer gate
918 contact
1000 sensor wafer
1002 unit cells
1004 circuit wafer
1006 unit cells
1007 inter-wafer interconnects
1008 column of unit cells
1010 column of unit cells
1012 column of unit cells
1014 column of unit cells
1016 arrow representing direction of shift
1100 unit cell
1102 photodetector
1104 photodetector
1106 transfer gate
1108 transfer gate
1110 charge-to-voltage conversion region
1112 contact
1114 inter-wafer interconnect
1200 unit cell
1202 photodetector
1204 photodetector
1206 photodetector
1208 photodetector
1210 transfer gate
1212 transfer gate
1214 transfer gate
1216 transfer gate
1218 charge-to-voltage conversion region
1220 contact
1222 inter-wafer interconnect
1300 sensor wafer
1302 color filter array
1304 microlens
1305 black color filter element
1306 circuit wafer
1308 charge-to-voltage conversion region
1310 gate of reset transistor
1312 potential
1314 gate of amplifier
1316 output of amplifier
1400 sensor wafer
1402 circuit wafer
1404 charge-to-voltage conversion region
1406 gate of reset transistor
1408 potential
1410 gate of amplifier
1412 output of amplifier
1414 metal shield
1416 electrical connector
1500 sensor wafer
1502 unit cell
1504 circuit wafer
1506 unit cell
1507 inter-wafer interconnect
1600 inter-wafer interconnect
1602 inter-wafer interconnect
1604 arrow representing direction of shift
1606 arrow representing direction of shift
1700 inter-wafer interconnect
1702 inter-wafer interconnect
1704 unit cell
1706 conductive layer
1708 contact
1800 inter-wafer interconnect
1802 inter-wafer interconnect
1804 conductive layer
1806 contact
1808 photodetector
1900 sensor wafer
1902 transfer gate
1904 charge-to-voltage conversion region
1906 wafer-to-wafer electrical interconnect
1908 interface between sensor wafer and circuit wafer
1910 circuit wafer
1912 charge-to-voltage conversion region
2000 sensor wafer
2002 transfer gate
2004 charge-to-voltage conversion region
2006 wafer-to-wafer electrical interconnect
2008 interface between sensor wafer and circuit wafer
2010 circuit wafer
2012 conductive layer
2014 charge-to-voltage conversion region
a distance between two adjacent inter-wafer interconnects
b distance between two adjacent inter-wafer interconnects
c interconnect pitch
d distance between two adjacent inter-wafer interconnects
e distance between two adjacent inter-wafer interconnects
f distance between inter-wafer interconnect and contact
D1 interconnect pitch
D2 interconnect pitch
M1 metal layer
M2 metal layer
M3 metal layer
M4 metal layer
M5 metal layer
M6 metal layer
M7 metal layer
M8 metal layer
M9 metal layer

1. An image sensor, comprising:
a sensor wafer comprising a first plurality of unit cells with each unit cell including at least one photodetector and a charge-to-voltage conversion region;
a circuit wafer comprising a second plurality of unit cells each including an electrical node associated with each unit cell on the sensor wafer;
an inter-wafer interconnect electrically connected between each charge-to-voltage conversion region on the sensor wafer and a respective electrical node on the circuit wafer, wherein a location of at least a portion of the inter-wafer interconnects is shifted a predetermined distance with respect to a location of the charge-to-voltage conversion region or the electrical node connected to each shifted inter-wafer interconnects; and
a conductive layer electrically connected between each shifted inter-wafer interconnect and the charge-to-voltage conversion region or the electrical node connected to the shifted inter-wafer interconnect.

2. The image sensor of claim 1, wherein the location of at least a portion of the inter-wafer interconnects are shifted a predetermined distance with respect to the location of each charge-to-voltage conversion region on the sensor wafer connected to shifted inter-wafer interconnects.

3. The image sensor of claim 1, wherein the location of at least a portion of the inter-wafer interconnects are shifted a predetermined distance with respect to the location of each electrical node on the circuit wafer connected to shifted inter-wafer interconnects.

4. The image sensor of claim 1, wherein the location of at least a portion of the inter-wafer interconnects are shifted a predetermined distance with respect to the location of each charge-to-voltage conversion region on the sensor wafer and with respect to each electrical node on the circuit wafer connected to shifted inter-wafer interconnects.

5. The image sensor of claim 1, wherein each electrical node on the circuit wafer connects to a charge-to-voltage conversion region on the circuit wafer.

6. The image sensor of claim 1, wherein each electrical node on the circuit wafer connects to a gate of an amplifier on the circuit wafer.

7. The image sensor of claim 1, wherein each unit cell on the sensor wafer includes two photodetectors and a shared charge-to-voltage conversion region.

8. The image sensor of claim 1, wherein each unit cell on the sensor wafer includes four photodetectors and a shared charge-to-voltage conversion region.

9. An image capture device, comprising:
an image sensor, comprising:
a sensor wafer comprising a first plurality of unit cells with each unit cell including at least one photodetector and a charge-to-voltage conversion region;
a circuit wafer comprising a second plurality of unit cells each including an electrical node associated with each unit cell on the sensor wafer;
an inter-wafer interconnect connected between each charge-to-voltage conversion region on the sensor wafer and a respective electrical node on the circuit wafer, wherein a location of at least a portion of the inter-wafer interconnects is shifted a predetermined distance with respect to a location of the charge-to-voltage conversion region or the electrical node connected to each shifted inter-wafer interconnects; and
a conductive layer electrically connected between each shifted inter-wafer interconnect and the charge-to-voltage conversion region or the electrical node connected to the shifted inter-wafer interconnect.

10. The image capture device of claim 9, wherein the location of at least a portion of the inter-wafer interconnects are shifted a predetermined distance with respect to the location of each charge-to-voltage conversion region on the sensor wafer connected to shifted inter-wafer interconnects.

11. The image capture device of claim 9, wherein the location of at least a portion of the inter-wafer interconnects are shifted a predetermined distance with respect to the location of each electrical node on the circuit wafer connected to shifted inter-wafer interconnects.

12. The image capture device of claim 9, wherein the location of at least a portion of the inter-wafer interconnects are shifted a predetermined distance with respect to the location of each charge-to-voltage conversion region on the sensor wafer and with respect to each electrical node on the circuit wafer connected to shifted inter-wafer interconnects.

13. The image capture device of claim 9, wherein each electrical node on the circuit wafer connects to a charge-to-voltage conversion region on the circuit wafer.

14. The image capture device of claim 9, wherein each electrical node on the circuit wafer connects to a gate of an amplifier on the circuit wafer.

15. The image capture device of claim 9, wherein each unit cell on the sensor wafer includes two photodetectors and a shared charge-to-voltage conversion region.

16. The image capture device of claim 9, wherein each unit cell on the sensor wafer includes four photodetectors and a shared charge-to-voltage conversion region.
